(19) United States
(12) Patent Application Publication
(10) Pub. No.: US 2025/0379081 A1
(43) Pub. Date: Dec. 11, 2025

(54) ENERGY EFFICIENT AUTOMATED MATERIAL HANDLING SYSTEM FOR SEMICONDUCTOR FABRICATION FACILITY

(71) Applicant: Taiwan Semiconductor Manufacturing Company, LTD., Hsinchu (TW)

(72) Inventors: Guancyun Li, Hsinchu (TW); Rong Syuan Fan, Taoyuan (TW); Ching-Jung Chang, Taichung (TW)

(21) Appl. No.: 18/735,387

(22) Filed: Jun. 6, 2024

(51) Int. Cl. H01L 21/677; H02J 7/00

(52) U.S. Cl. CPC H01L 21/67733; H01L 21/67712; H02J 7/0068

(57) ABSTRACT

In an automated material handling system (AMHS) of a semiconductor fabrication facility, a transfer operation is performed, including energizing a motor of an overhead transport (OHT) vehicle to move the OHT vehicle along an overhead track of the AMHS, or to operate a lifter of the OHT vehicle. During a deceleration phase of the transfer operation, kinetic energy of the OHT vehicle moving along the overhead track of the AMHS, or of the lifter of the OHT vehicle, is converted to recovered electrical energy that is stored in an energy storage device. A subsequent transfer operation performed by the AMHS is powered, at least in part, using the recovered electrical energy retrieved from the energy storage device. After completion of the transfer operation, the OHT vehicle may be placed into an idle state including opening a relay to electrically disconnect the energy storage device of the OHT vehicle.

### BACKGROUND

The following relates to semiconductor fabrication facilities, to an automated material handling system (AMHS) of a semiconductor fabrication facility, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a portion of an automated material handling system (AMHS) including an overhead track and a diagrammatically shown representative overhead transport (OHT) vehicle.

FIG. 2 diagrammatically illustrates a side sectional view of the portion of the AMHS of FIG. 1 operating to deliver electrical power to accelerate or drive the OHT vehicle or its lifter.

FIG. 3 diagrammatically illustrates a side sectional view of the portion of the AMHS of FIG. 1 engaged in kinetic energy recovery during deceleration of the OHT vehicle or its lifter.

FIG. 4 diagrammatically illustrates a side sectional view of the portion of the AMHS of FIG. 1 with the OHT vehicle at idle.

FIG. 5 diagrammatically illustrates an operational flow chart of operation of an OHT vehicle of an AMHS.

FIG. 6 diagrammatically illustrates a flow chart of operation of an OHT vehicle of an AMHS to perform a transfer operation with kinetic energy recovery.

FIG. 7 diagrammatically illustrates functional operations of material handling in a semiconductor fabrication facility.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some semiconductor fabrication facilities employ an automated material handling system (AMHS) employing overhead transport (OHT) vehicles that travel on overhead tracks of the AMHS and carry containers of semiconductor wafers such as front-opening unified pod (FOUP) containers between semiconductor processing or characterization tools of the semiconductor fabrication facility. This approach has numerous advantages, such as placing wafer transport overhead where it does not interfere with personnel, facilitating automated workflows by delivering containers of semiconductor wafers along preprogrammed routes through the semiconductor fabrication facility, and providing automated wafer transport that minimizes likelihood and extent of wafer contamination through close interaction with facility personnel.

Since the industrial revolution, greenhouse gas emissions have been increasing day by day. Today, more and more people are paying attention to energy issues. Semiconductor fabrication facilities consume a lot of power, and the AMHS is recognized herein as a substantial power consumer.

Disclosed herein are approaches for reducing the power consumption of AMHS through power recollection. Such power recovery can provide substantial energy savings for the semiconductor fabrication facility, and contributes to the sustainable development of the environment.

The OHT vehicles of the AMHS are motorized, typically including a travel motor that operates wheels, rollers, casters, drums, or the like to move the OHT vehicle along overhead tracks of the AMHS; and a lifter motor that operates a lifter of the OHT vehicle to raise or draw a container of semiconductor wafers to the OHT vehicle for overhead transport and lower or otherwise deliver the container to a load port of a semiconductor processing or characterization tool. To maximize speed of transport, these motors typically operate at 100% power when being utilized, and are at 0% power when not being utilized. The OHT vehicle thus travels maximum speed along the overhead track (e.g., at a speed of around 3-4 meters per second in some nonlimiting illustrative examples). Likewise, the lifter of the OHT vehicle raises and lowers the container of semiconductor wafers at maximum speed (e.g., at a speed of around 0.5-2 meters per second in some nonlimiting illustrative examples).

It is recognized herein that the kinetic energy incurred during transfer operations performed by the OHT vehicles can be recovered and reused by the AMHS to increase the energy efficiency of the AMHS. A transfer operation may include energizing the travel motor of the OHT vehicle to move the OHT vehicle along the overhead track of the AMHS, or energizing the lifter motor of the OHT vehicle to operate the lifter of the OHT vehicle. During a deceleration phase of the transfer operation, kinetic energy of the OHT vehicle moving along the overhead track of the AMHS, or kinetic energy of the lifter of the OHT vehicle, is converted to recovered electrical energy and stored in an energy storage device, either onboard the OHT vehicle or offboard. The recovered electrical energy is subsequently used to power (at least in part) a subsequent transfer operation performed by an OHT vehicle of the AMHS.

The deceleration phase of the transfer operation is a time interval at or near the end of the transfer operation in which the movement decelerates. In the case of transfer of the OHT vehicle, the deceleration phase is the time during which the OHT vehicle decelerates as it approaches its final position above the tool load port or other final target position of the transfer operation. In the case of a lifter operation, the deceleration phase is the time when lifter mechanism (e.g., a rotating drum or lift-wheel or other rotating element of a hoist, or a moving shaft or robotic arm or other lifter mechanism) of the lifter decelerates. The deceleration phase of the transfer operation will typically coincide with a cessation or rapid reduction in electrical power delivered to the motor. The kinetic energy can be translational kinetic energy, e.g., the translational kinetic energy of the OHT vehicle moving along the overhead track of the AMHS, or can be rotational kinetic energy, e.g., the rotational kinetic energy of a rotating drum or lift-wheel of the lifter used in the transfer operation.

It is further recognized herein that an idling OHT vehicle is another source of wasted power in operation of the AMHS. An OHT vehicle may be idle for various reasons. For example, the OHT vehicle may be preprogrammed to remain overhead of the load port of a semiconductor processing or characterization tool while the tool is processing or characterizing semiconductor wafers from a container of semiconductor wafers being transported by the OHT vehicle. This type of idle time may in some instances be reduced by efficient routing of the OHT vehicles—for example, during the semiconductor wafer processing or characterization the OHT vehicle might be used to transfer another container of semiconductor wafers. However, the complexity of routing many batches of semiconductor wafers in many containers moving throughout the semiconductor fabrication facility, and practical limitations such as avoiding having two OHT vehicles at the same location on the overhead tracks (i.e., avoiding OHT vehicle collisions), imposes limitations on routing efficiency. Another reason for an OHT vehicle to be idle is unexpected problems with the semiconductor processing workflow. For example, if a semiconductor processing or characterization tool breaks down, then OHT vehicles preprogrammed to transport containers of semiconductor wafers to and from that tool may be idle until the semiconductor processing or characterization tool is repaired and brought back online.

An idle OHT vehicle might be expected to consume little or no power. However, it is recognized herein that an idle OHT vehicle still consumes power due to electrical connection of its onboard battery with power consuming components, especially the travel motor and lifter motor. In view of this recognition, some embodiments disclosed herein provide a relay which is used to place the idle OHT vehicle into an idle state which includes opening the relay to electrically disconnect the onboard energy storage device of the OHT vehicle. This minimizes electrical power drain from the energy storage device (e.g., a battery or storage capacitor) and thereby further increases the energy efficiency of the AMHS.

Control of these energy saving mechanisms can be local, with each OHT vehicle controlling its own kinetic energy recovery operations and controlling its relay to isolate its battery when the OHT vehicle is idle. The kinetic energy converted to recovered electrical energy can be stored in the onboard energy storage device of the OHT vehicle.

Additionally or alternatively, the AMHS controller can implement AMHS-wide control of these energy saving mechanisms. In this case, the AMHS controller sends signals to the OHT vehicles based on sensor data from the OHT vehicles, e.g., wirelessly conveyed to the AMHS controller by WiFi or another wireless Tx/Rx communication protocol. Centralized energy recovery control by the AMHS controller can further increase the energy efficiency of the AMHS. Centralized control also optionally can increase the storage capacity for the recovered electrical energy by coordinating transfer of recovered electrical energy from the onboard energy storage devices of the OHT vehicles to an AMHS-level energy storage device, e.g., at a power panel of the AMHS. This can improve energy efficiency in situations where the onboard energy storage device of an OHT vehicle is already near capacity such that it might not be able to efficiently store the recovered electrical energy at the OHT vehicle.

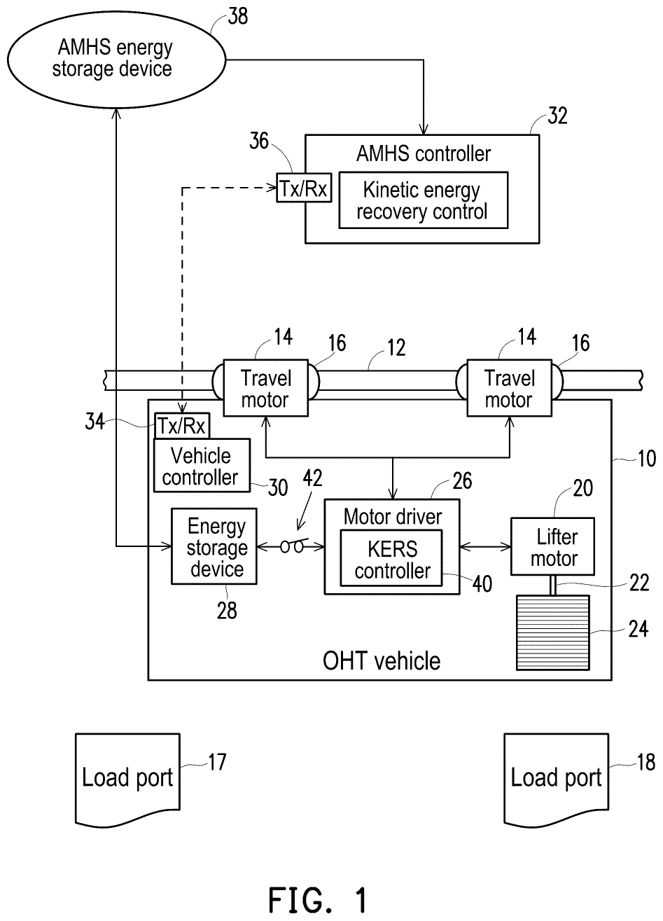

With reference to FIG. 1, a side sectional view of a portion of an automated material handling system (AMHS) is diagrammatically illustrated, including an illustrative OHT vehicle 10 shown secured to an overhead track 12 of an AMHS. Only a portion of the overhead track 12 located above the present position of the OHT vehicle 10 is shown in FIG. 1. Furthermore, FIG. 1 illustrates the overhead track 12 in side view. In various embodiments, the overhead track 12 may consist of a single track or rail (e.g., a monorail), a pair of tracks or rails, or other track configuration. Movement of the OHT vehicle 10 along the overhead track 12 is performed using a travel motor 14 (implemented as two travel motors in the nonlimiting illustrative example) driving wheels, rollers, casters, drums, or the like 16 of the OHT vehicle 10 that are engaged with the overhead track 12 to move the OHT vehicle 10 along the overhead track 12. By way of such movement along the overhead track 12, the OHT vehicle 10 moves along the overhead track 12 from a position above a first semiconductor processing or characterization tool load port 17 to a position above a second semiconductor processing or characterization tool load port 18. The load ports 17 and 18 are diagrammatically indicated in FIG. 1, and typically the load ports 17 and 18 may be located a substantial distance apart, e.g., meters, tens of meters, or further apart. Moreover, the path from the load port 17 to the load port 18 may be curved, angled, or otherwise non-straight, as accommodated by suitable curvature, angling, or other non-straight path of the portion of the overhead track 12 running between load ports 17 and 18.

The OHT vehicle further includes a lifter motor 20 that operates a lifter 22 to raise or lower a container 24 of semiconductor wafers. The lifter 22 is diagrammatically shown by a hoist cable or lift shaft or robotic arm. More generally, the lifter 22 may be a hoist that includes a cable that is raised or lowered using a drum or lift-wheel or other rotating element driven by the lifter motor; or, the lifter may have another configuration such as a telescoping shaft or robot arm or the like that is extended or withdrawn by operation of the lifter motor 20. These are merely nonlimiting illustrative examples. If the lifter 22 is a hoist, then the OHT vehicle 10 may alternatively be referred to as an Overhead Hoist Transport vehicle 10. In some embodiments, the lifter 22 may include the capability (e.g., via an articulated robot arm) to move the container 24 laterally in addition to (or alternative to) raising or lowering the container 24 vertically. Moreover, while the container 24 is described herein as a container 24 of semiconductor wafers, which is a typical material transported by the AMHS of a semiconductor fabrication facility, it is contemplated for the container 24 to contain another material used in a semiconductor fabrication facility, such as (by way of a further nonlimiting illustrative example) a consumable chemical used by a semiconductor processing or characterization tool. It is also noted that FIG. 1 is diagrammatic, and that in practice the lifter 22 may be located elsewhere in the OHT vehicle 10 than as depicted. For example, in some OHT vehicle designs the lifter 22 is centrally located within the OHT vehicle 10 to provide improved load balancing (e.g., a center of mass located near the geometrical center of the OHT vehicle).

The travel motor 14 (illustrative two travel motors) driving the wheels, rollers, casters, drums, or the like 16 driving the OHT vehicle 10 along the overhead track 12, and the lifter motor 20 operating the lift 22, are illustrated in FIG. 1 as separate motors. However, it is alternatively contemplated for the travel motor and the lifter motor to be a single motor, with suitable gearing or the like for switching between (i) driving the wheels, rollers, casters, drums, or the like 16 that move the OHT vehicle 10 along the overhead track 12, and (ii) driving the lifter 22 to retrieve or place the container 24 from or onto a load port 17 or 18, respectively.

The OHT vehicle 10 further includes a motor controller 26 for controlling the motors 14 and 20. More particularly, the motor controller 26 performs a transfer operation including energizing the travel motor 14 of the OHT vehicle 10 to move the OHT vehicle 10 along the overhead track 12 of the AMHS, or energizing the lifter motor 20 to operate the lifter 22 of the OHT vehicle 10. An onboard energy storage device 28, such as an onboard battery, storage capacitor, electrostatic double-layer capacitor, or the like stores electrical energy that is conveyed by the motor controller 26 to the appropriate motor 14 or 20 to cause the appropriate motor to operate to perform the transfer operation. The OHT vehicle 10 further includes a vehicle controller 30, such as a microprocessor or microcontroller with suitable ancillary electronics (e.g., a solid state memory storing programming code) and controls the motor driver 26 and optionally other functions of the OHT vehicle 10. While illustrated in FIG. 1 as a separate component, it is contemplated for the vehicle controller 30 to be integrated with the motor driver 26.

As previously mentioned, FIG. 1 diagrammatically illustrates a side sectional view of a portion of an AMHS, including a diagrammatic side sectional view of the OHT vehicle 10 and a portion of the overhead track 12. The AMHS typically includes a plurality of such OHT vehicles 10, e.g., dozens or more OHT vehicles in some complex AMHS systems for a large semiconductor fabrication facility. Likewise, the illustrated portion of the overhead track 12 is representative of an extensive network of overhead track distributed over much, or all, of the ceiling or other overhead structure of the semiconductor fabrication facility. The network of overhead track 12 typically includes intersecting tracks with suitable electromechanical track switches or the like (not shown) for routing a moving OHT vehicle along the correct preprogrammed overhead path through the semiconductor fabrication facility.

The overall operation of the AMHS is controlled by an AMHS controller 32, which may be in wireless communication with the OHT vehicles 10 by way of a wireless transceiver (Tx/Rx) 34 included in each OHT vehicle 10, which communicate with one or more transceivers (Tx/Rx) 36 of the AMHS controller 32. By way of one nonlimiting illustrative example, the wireless transfer protocol may be WiFi, the wireless transceivers 34 of the OHT vehicles 10 may be WiFi radios built into the OHT vehicles 10, and the wireless transceiver(s) 36 of the AMHS controller 32 may be a set of WiFi access points (APs) distributed throughout the semiconductor fabrication facility.

The AMHS controller 32 controls AMHS-wide operations, and also may implement preprogrammed transport recipes or programs that are carried out by the OHT vehicles 10. By way of nonlimiting illustrative example, the AMHS controller 32 may control or operate track switches to direct moving OHT vehicles along the correct route, send commands to the OHT vehicles 10 to perform various transfer operations, and/or so forth. As one nonlimiting specific example, the AMHS controller 32 may send a sequence of commands to the illustrative OHT vehicle 10 to cause it to perform a sequence of transfer operations including: (1) a first transfer operation in which the lifter 22 is operated by the lifter motor 20 to retrieve the container 24 of semiconductor wafers from the first load port 17; (2) a second transfer operation in which the OHT vehicle 10 is driven by the travel motor 14 along the overhead track 12 from a position above the first load port 17 to a position above the second load port 18; and (3) a third transfer operation in which the lifter 22 is operated by the lifter motor 20 to place the container 24 of semiconductor wafers onto the second load port 18. These three combined transfer operations are thus operative to move the container 24 of semiconductor wafers from the first load port 17 to the second load port 18. A more extended sequence of similar transfer operations can transport the container 24 of semiconductor wafers along a preprogrammed workflow through the semiconductor processing facility, advantageously with little or no intervention by facility workers.

While the foregoing describes the AMHS controller 32 as sending individual transfer operation commands, it is alternatively contemplated for the OHT vehicle 10 to incorporate and execute some programming locally at the OHT vehicle 10 to perform certain operations autonomously at the OHT vehicle 10, e.g., by executing suitable code at the vehicle controller 30. For example, the AMHS controller 32 may send a command to move the container 24 of semiconductor wafers from the first load port 17 to the second load port 18, and the vehicle controller 30 then responds by autonomously executing the previously described sequence of first, second, and third transfer operations to implement that command. More generally, the processing can be variously distributed between centralized processing at the AMHS controller 32 and local processing performed autonomously at the individual OHT vehicles 10.

The AMHS may optionally include an AMHS energy storage device 38 separate from the onboard energy storage devices 28 of the OHT vehicles 10. The AMHS energy storage device 38 is therefore also referred to herein as an offboard energy storage device 34, as it is not located on the OHT vehicles 10. The AMHS energy storage device 38 may be a battery, storage capacitor, electrostatic double-layer capacitor, a bank of such batteries or capacitors, various combinations thereof, or the like. The AMHS energy storage device 38 suitably provides electrical power for AMHS operations such as operating track switches of the network of overhead track 12, powering the AMHS controller 32, and other AMHS-wide functions. Optionally, the AMHS energy storage device 38 may also deliver electrical power via power conductors incorporated into the overhead track 12 to recharge the onboard energy storage devices 28 of the fleet of OHT vehicles 10.

The illustrative AMHS incorporates various energy saving mechanisms to increase the energy efficiency of the AMHS and of the individual OHT vehicles 10. In one illustrative aspect, these energy saving mechanisms include providing a kinetic energy recovery system (KERS) controller 40 integrated with the motor driver 26. The KERS controller 40 is operative to convert kinetic energy produced during the transfer operations (e.g., kinetic energy of the OHT vehicle 10 moving along the overhead track 12, or kinetic energy of the lifter 22 used in the transfer operation) into recovered electrical energy and store the recovered electrical energy in the onboard energy storage device 28.

In another illustrative aspect, a relay 42 is provided to disconnect the onboard energy storage device 28 of the OHT vehicle 10 during an idle interval during which the OHT vehicle is not performing transfer operations. The relay 42 may be a solenoid-driven relay, or a solid state relay such as a thyristor, transistor, silicon-controlled rectifier (SCR), a TRIAC, or so forth. Opening the relay 42 when the OHT vehicle is not being used to perform transfer operations minimizes electrical power drain from the energy storage device 28 and thereby further increases the energy efficiency of OHT vehicle 10 (and thereby of the AMHS).

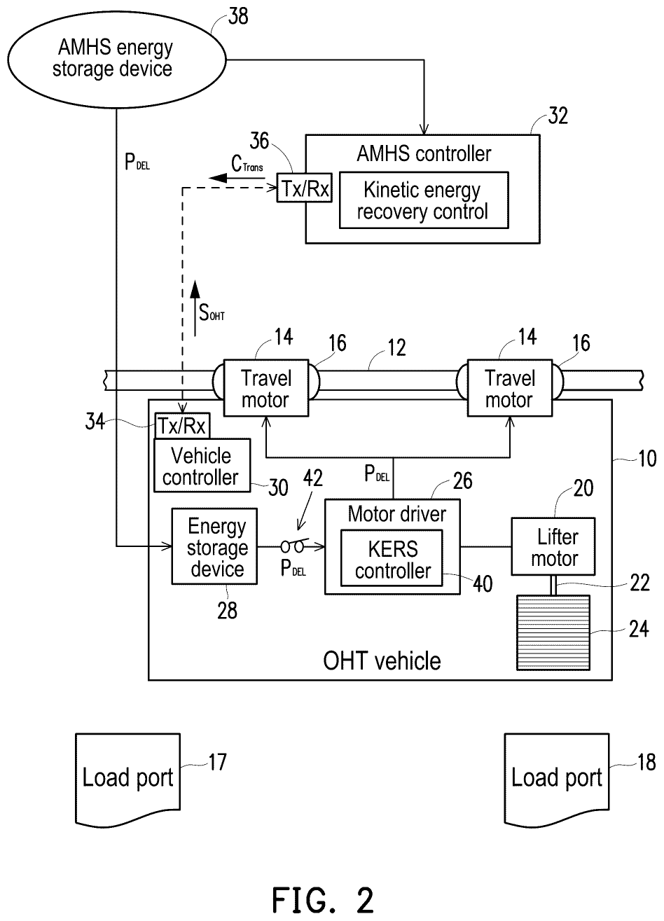

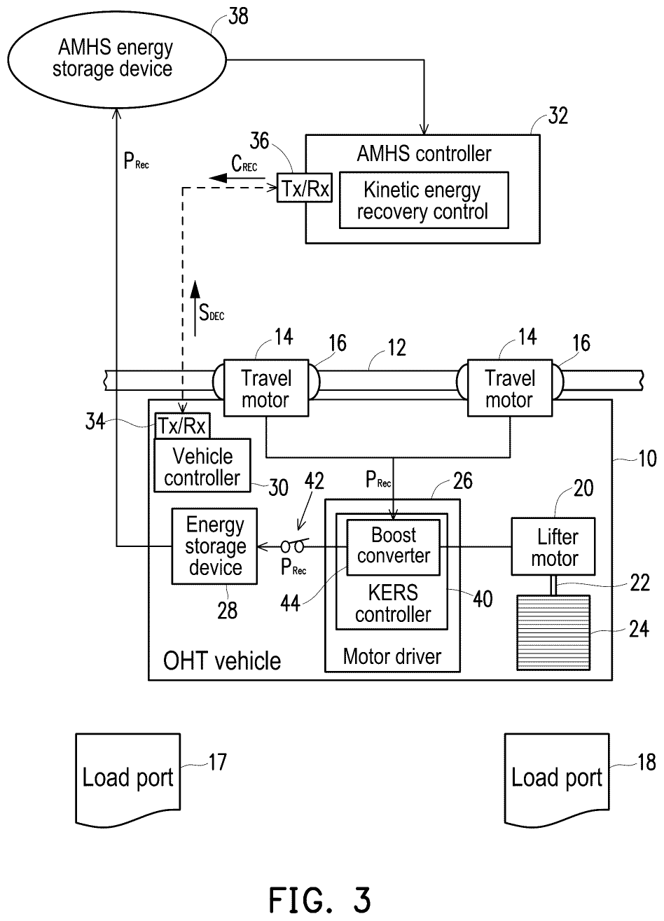

With reference to FIGS. 2 and 3, operation of the kinetic energy recovery is described. In both FIGS. 2 and 3, the relay 42 is closed to connect the onboard energy storage device 28 with the motor driver 26. As diagrammatically shown in FIG. 2, the AMHS controller 32 transmits a command C_{Trans} to the OHT vehicle 10 to perform a transport operation via the wireless link 34, 36. In response, the motor driver 26 energizes the travel motor 14 using electricity from the onboard energy storage device 28 to deliver electrical power (P_{Del}) to drive the wheels, rollers, casters, drums, or the like 16 to move the OHT vehicle 10 along the overhead track 12. Optionally, the speed of the OHT vehicle 10 during the transfer operation is measured by a sensor (for example, an indirect measurement of voltage or current or another operating parameter of the travel motor 14, or an accelerometer that directly measures the speed, or a rotation speed sensor integrated into the wheels, rollers, casters, drums, or the like 16), and the OHT vehicle 10 optionally sends a signal SOHT indicative of the measured speed of the OHT vehicle 10 to the AMHS controller 32 via the wireless link 34, 36. During this phase of the transport operation, the KERS controller 40 of the motor drive 26 is not operative. As the OHT vehicle 10 approaches the final position (e.g., above the second or destination load port 18 in the illustrative embodiment) the transfer operation enters a deceleration phase in which the OHT vehicle 10 decelerates to stop at the final position.

FIG. 3 diagrammatically illustrates a side sectional view of the portion of the AMHS of FIG. 1 engaged in kinetic energy recovery during the deceleration of the OHT vehicle or its lifter. Switching circuitry of the KERS controller 40 connects a boost converter 44 between the travel motor 14 and the onboard energy storage device 28 to perform the energy recovery. In the kinetic energy recovery, the travel motor 14 now operates as an electrical generator to convert the kinetic energy of the moving OHT vehicle 10 (via the rotating wheels, rollers, casters, drums, or the like 16) to recovered electrical energy which is stored in the onboard energy storage device 28. A subsequent transfer operation performed by the OHT vehicle 10 may then be powered at least in part using the recovered electrical energy retrieved from the energy storage device 28.

The example of FIGS. 2 and 3 depicts kinetic energy recovery during a transfer operation that includes energizing the travel motor 14 of the OHT vehicle 10 to move the OHT vehicle 10 along the overhead track 12 of the AMHS, and during the deceleration converting the kinetic energy of the OHT vehicle 10 moving along the overhead track 12 of the AMHS to recovered electrical energy. For example, the OHT vehicle 10 may be transporting a container 14 containing semiconductor wafers undergoing processing at the semiconductor fabrication facility, and the transfer operation comprises moving the OHT vehicle 10 along the overhead track 12 of the AMHS from a position above a first semiconductor processing or characterization tool load port 17 to a position above a second semiconductor processing or characterization tool load port 18.

Although not illustrated, the same approach employed in FIGS. 2 and 3 for recovering kinetic energy can be applied to operation of the lifter 22. Here, the transfer operation includes energizing the lifter motor 20 of the OHT vehicle 10 to operate the lifter 22 of the OHT vehicle, and during deceleration of the lifter 22 converting kinetic energy of the lifter 22 used in the transfer operation to recovered electrical energy. In one example, the transfer operation entails lowering the container 14 containing semiconductor wafers undergoing processing at the semiconductor fabrication facility from the OHT vehicle 10 onto a semiconductor processing or characterization tool load port 18. In another example, the transfer operation entails raising the container 14 containing the semiconductor wafers undergoing processing at the semiconductor fabrication facility from the semiconductor processing or characterization tool load port 18 to the OHT vehicle 10.

In one implementation approach for kinetic energy recovery, a parameter indicative of the movement of the OHT vehicle 10 along the overhead track 12 of the AMHS, or of the lifter 22 of the OHT vehicle 10, is sensed, and switching from the transfer operation (FIG. 2) to the performing of kinetic energy recovery (FIG. 3) based on the parameter indicating a deceleration of the OHT vehicle 10 or of the lifter 22 of the OHT vehicle 10. The sensed parameter for a transfer operation involving moving the OHT vehicle 10 may, for example, be an electric current or voltage of the operating travel motor 14, or a direct measurement of speed of the OHT vehicle 10 or a surrogate thereof such as a rotation speed of the wheels, rollers, casters, drums, or the like 16 of the OHT vehicle 10 that are engaged with the overhead track 12, or so forth. The sensed parameter for a transfer operation involving operation of the lifter 22 may, for example, be an electric current or voltage of the operating lift motor 20, or a direct measurement of movement of the lifter 22 such as a rotation speed of a rotating drum or lift-wheel or other rotating element of the lifter 22 (e.g., if the lifter 22 comprises a hoist), or a sensor monitoring movement of a moving shaft or robotic arm or other lifter mechanism.

As previously noted, the recovered electrical energy from the kinetic energy recovery system is stored in the onboard energy storage device 28, and may then be retrieved and used to power (at least in part) a subsequent transfer operation performed by the OHT vehicle 10.

Additionally, in some embodiments, some or all of the recovered electrical energy may be stored in an offboard energy storage device not disposed on the OHT vehicle, such as in the illustrative AMHS energy storage device 38 which is separate from the onboard energy storage devices 28 of the OHT vehicles 10. In such embodiments, the recovered electrical energy may include initially storing the recovered electrical energy in the onboard OHT vehicle energy storage device 28, and then transferring at least a portion of the recovered electrical energy from the onboard energy storage device 28 to the offboard energy storage device 38 via the overhead track 12 of the AMHS. To this end, the overhead track 12 may include electrical conductors (not shown) connected to convey electrical energy to and from the AMHS energy storage device 38, and the OHT vehicle 10 may include electrodes in the form of electrically conductive brushes or the like (not shown) that can be moved to engage with or disengage from the track electrical conductors. The AMHS controller 32 suitably controls such energy transfer, for example by sending a signal C_{Trans} indicated in FIG. 2 via the wireless link 34, 36 to coordinate transfer of electrical energy from the AMHS energy storage device 38 to the onboard energy storage device 28. Likewise, the AMHS controller 32 may send a signal C_{Rec} indicated in FIG. 3 via the wireless link 34, 36 to coordinate transfer of electrical energy from the onboard energy storage device 28 to the AMHS energy storage device 38 to transfer (at least a portion of) the recovered electrical energy to the offboard AMHS energy storage device 38. The coordination may also include sending a sensor signal S_{Dec} from the OHT vehicle 10 to the AMHS controller 32 via the wireless link 34, 36 to inform the AMHS controller 32 of when the OHT vehicle 10 (or the lifter 22 thereof) enters the deceleration phase of the transfer operation.

The optional ability to transfer recovered electrical energy to and from the offboard energy storage device 38 has certain advantages. In situations in which the onboard energy storage device 28 is already at or near its maximum electrical charge storage limit, there is minimal benefit to further storing the recovered electrical energy provided by the kinetic energy recovery in the onboard storage device 28. Such storage may be inefficient, and if the onboard energy storage device is at full capacity such storage may be impossible. By transferring recovered electrical energy between the AMHS energy storage device 38 and the onboard energy storage devices 28 of the OHT vehicles 10 of the AMHS, the recovered electrical energy can be more efficiently stored and reused. The AMHS energy storage device 38 may be a large bank of batteries or the like with substantially higher electrical energy storage capacity than the individual onboard energy storage devices 28 of the OHT vehicles 10. In this way, for example, a subsequent transfer operation performed by a different OHT vehicle of the AMHS may be powered at least in part using the recovered electrical energy retrieved from the offboard AMHS energy storage device 38.

In the embodiments of FIGS. 2 and 3, the relay 42 is closed to connect the onboard energy storage device 28 with the motor driver 26. This is the normal operational setting of the relay 42.

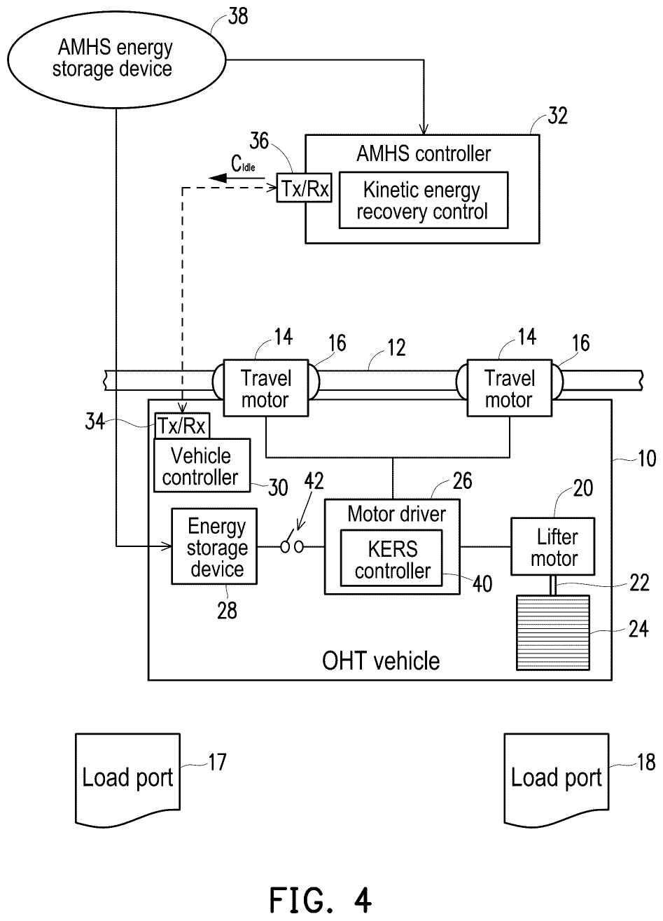

FIG. 4 diagrammatically illustrates a side sectional view of the portion of the AMHS of FIG. 1 with the OHT vehicle at idle. As previously noted, the relay 42 is provided to disconnect the onboard energy storage device 28 of the OHT vehicle 10 during an idle interval during which the OHT vehicle is not performing transfer operations. This is illustrated in FIG. 4. The relay 42 may be a solenoid-driven relay, or a solid state relay such as a thyristor, transistor, silicon-controlled rectifier (SCR), a TRIAC, or so forth. Opening the relay 42 when the OHT vehicle is not being used to perform transfer operations minimizes electrical power drain from the energy storage device 28 and thereby further increases the energy efficiency of OHT vehicle 10 (and thereby of the AMHS). Thus, after completion of a transfer operation, the OHT vehicle 10 may be placed into an idle state including opening the relay 42 as shown in FIG. 4 to electrically disconnect the energy storage device 28 of the OHT vehicle 10. This avoids potential energy drain from the energy storage device 28 by the electronics of the motor driver 26, which otherwise may draw some electrical power even when not being used to perform a transfer operation. Such power draw can, by way of nonlimiting illustrative example, include power drawn by integrated circuitry and/or transistors of the boost converter 44 and/or other electronics of the motor driver 26, power drawn by windings of the non-operating motors 14 and 20, and/or so forth.

The opening and closing of the relay 42 may be controlled locally by the vehicle controller 30 of the OHT vehicle 10, and/or by the AMHS controller 32. In the illustrative example of FIG. 4, the AMHS controller 32 sends an idle signal C_{Idle} to the OHT vehicle 10 via the wireless link 34, 36 to command the OHT vehicle 10 to enter idle mode including opening the relay 42. Cycling the relay 42 between open and closed can itself produce transitional power draw (e.g., when powering up the motor driver 26 after closing the relay 42 to exit idle mode). Thus, having the AMHS controller 32 command the OHT vehicle 10 to enter idle mode can be advantageous as the AMHS controller 32 has access to the semiconductor fabrication workflow and information about unplanned events. So, for example, in the event of an unplanned shutdown of a semiconductor fabrication or characterization tool, the AMHS controller 32 can place affected OHT vehicles 10 into idle until the shutdown is resolved and the affected OHT vehicles 10 are again utilized to transport material two and from the tool.

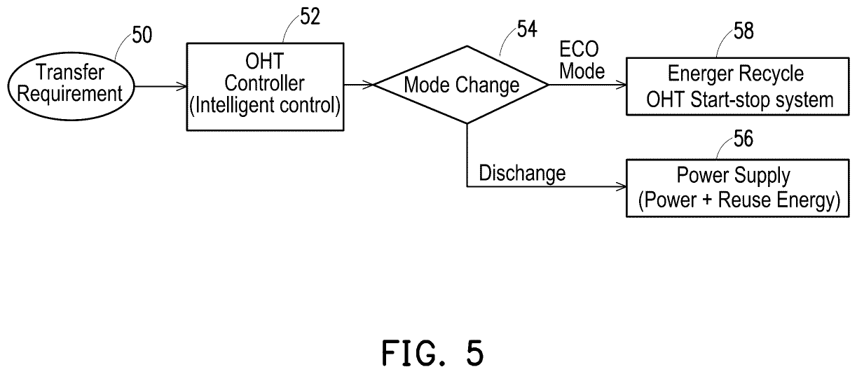

With reference to FIG. 5, operation of the kinetic energy recovery system and relay 42 for maximizing energy efficiency of the AMHS is diagrammatically illustrated. A transfer operation (i.e., “transfer requirement”) 50 is initiated and/or received by the vehicle controller (i.e., “OHT controller”) 30 and/or the AMHS controller 32 (collectively referred to as an OHT controller 52 in FIG. 5). During the transfer operation the OHT controller 52 controls a mode change 54 to switch the motor driver 26 to a discharge mode 56 in which power is drawn from the onboard energy storage device 28 to perform the transfer operation 52 (e.g., corresponding to FIG. 2). This may include drawing recovered electrical energy that was stored in the onboard energy storage device 28 during a previous transfer operation to perform the current transfer operation. During a deceleration phase of the transfer operation the OHT controller 52 issues a mode change 54 to switch the motor driver 26 to an energy recycling mode (i.e., economy mode or “ECO” mode) 58 in which kinetic energy recover is performed (e.g., corresponding to FIG. 3). The ECO mode 58 may also include placing the OHT vehicle 10 into idle if not being used by opening the relay 42, e.g. corresponding to FIG. 4. In the illustrative example of FIG. 5, the OHT controller performs intelligent control to maximize energy efficiency of the OHT vehicle 10 (and, by virtue of analogous KERS and idle relay open implementation at all OHT vehicles of the AMHS, to also maximize energy efficiency of the AMHS as a whole). As previously discussed, the OHT controller 52 functionality can be variously distributed between the AMHS controller 32 and the vehicle controller 30. For example, the AMHS controller 32 may issue high level commands such as the transfer requirement 50 and the vehicle controller 30 may issue lower-level commands such as controlling the mode change 52 to implement the transfer with kinetic energy recovery. In another example, the AMHS controller 32 may provide lower-level control such as directly controlling the mode changes 54. In some embodiments, the AMHS controller 32 may additionally or alternatively coordinate transfer of (a portion of) the recovered electrical energy from kinetic energy recovery between the onboard energy storage devices 28 of the OHT vehicles 10 and the AMHS energy storage device 38. These are merely some nonlimiting illustrative examples.

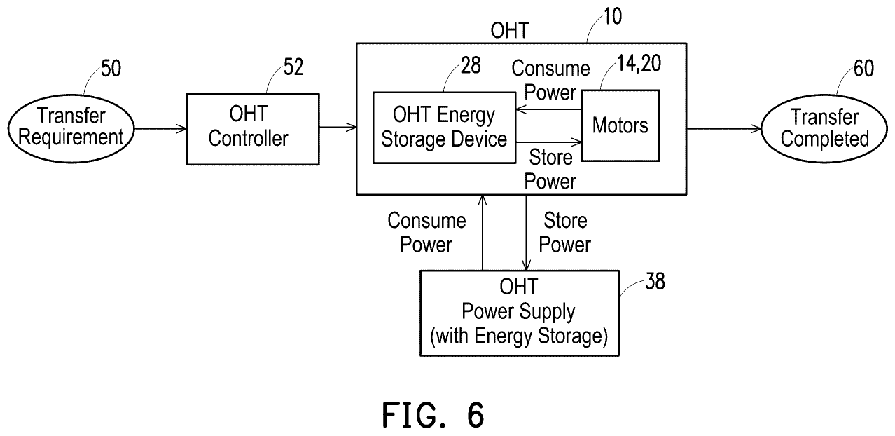

With reference to FIG. 6, some examples of power flow during a transfer operation including kinetic energy recovery is shown. The transfer requirement or operation 50 is implemented by the OHT controller 52 and the OHT vehicle 10 (referred to simply as the OHT 10 in FIG. 6). During the discharge phase 56 of the transfer operation, the motor 14 or 20 consumes electrical power from the onboard energy storage device 28 and/or from the AMHS energy storage device 38, as indicated by arrows labeled “Consume power” in FIG. 6. During the deceleration phase (i.e., ECO mode 58), the motor 14 or 20 switches to electrical energy generation driven by the kinetic energy produced during the transfer operation, and this recovered electrical energy is stored in the onboard electrical energy storage device 28, as indicated by arrows labeled “Store power” in FIG. 6. Thus, the transfer is completed 60 with reduced total energy draw due to the recovery of (at least a portion of) the kinetic energy.

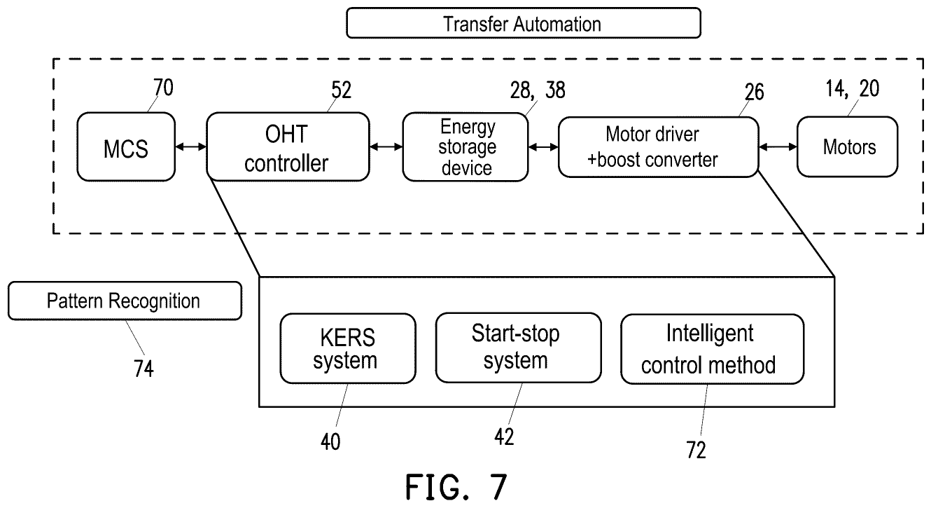

With reference to FIG. 7, functional operations of material handling in a semiconductor fabrication facility are diagrammatically illustrated. A manufacturing control system (MCS) or manufacturing execution system (MES) or manufacturing operations system MOM) or similar system 70 controls overall workflow in the semiconductor fabrication facility, including sending commands to the AMHS to perform transfer operations which are carried out by OHT vehicles 10 of the AMHS. As shown in FIG. 7, this involves control of transfer operations by the OHT controller 52 (e.g., including the AMHS controller 32 and/or vehicle controllers 30 of the individual OHT vehicles 10), electrical energy storage in the onboard energy storage devices 28 of the individual OHT vehicles 10 and/or in the AMHS energy storage device 38) which powers the motor drivers 26 with boost converters 44 to operate the motors 14, 20 of the OHT vehicles 10 to perform the transfer operations with kinetic energy recovery and idle state power disconnection (i.e., start/stop) using the relays 42 of the OHT vehicles 10. In this way, the AMHS implements the KERS systems 40 and relays 42 of the OHT vehicles 10. An intelligent control method 72 implemented at the OHT controller 52 controls the kinetic energy recovery and start-stop system to maximize energy efficiency of the AMHS. In some embodiments, pattern recognition 74 is employed in the intelligent control method 72 to optimize the implementation of the KERS and start-stop system. For example, patterns of how the OHT vehicles approach and come to rest above a particular load port 17 or 18, and how the lifter 20 places and removes FOUPs 24 onto and off the load port 17 or 18, can be analyzed by inputting training data comprising numerous historical executions of such transfer operations to determine the optimal time at which the mode change 54 (see FIG. 5) should be switched from discharge mode 56 to ECO mode 58 to ensure smooth completion of the transfer operation with maximum kinetic energy recovery. In some embodiments, adaptive training of the intelligent control method 72 may be utilized. For example, if instances of a OHT vehicle travel operation from load port 17 to load port 18 are beginning energy recover too soon then the adaptive training can switch to ECO mode later in the transfer operation for subsequent instances of that OHT vehicle travel operation.

The illustrative embodiments include all of the motor driver 26 with the kinetic energy recovery controller 40 for both travel and lift operation, and idle mode power saving via the relay 42. However, it is contemplated to include a subset of these energy-saving aspects.

Thus, in some nonlimiting illustrative embodiments, a specific AMHS implementation provides kinetic energy recovery during transfer operations that energize the travel motor 14 to move the OHT vehicle 10 along the overhead track 12 of the AMHS, but not during transfer operations that energize the lift motor to operate the lift.

In some nonlimiting illustrative embodiments, a specific AMHS implementation provides kinetic energy recovery during transfer operations that energize the lifter motor 20 to operate the lift 22, but not during transfer operations that energize the travel motor to move the OHT vehicle along the overhead track.

In some nonlimiting illustrative embodiments, a specific AMHS implementation provides kinetic energy recovery during transfer operations that energize the travel motor 14 to move the OHT vehicle 10 along the overhead track 12 of the AMHS, and also during transfer operations that energize the lifter motor 20 to operate the lift 22.

In any of these example specific AMHS implementations may further include the relay 42, or may omit the relay 42. nonlimiting illustrative embodiments, a specific AMHS implementation provides the relay 42 but not the kinetic energy recovery aspect.

In the following, some further embodiments are described.

In a nonlimiting illustrative embodiment, a method of operating an automated material handling system (AMHS) of a semiconductor fabrication facility is disclosed. The method includes: performing a transfer operation including energizing a motor of an overhead transport (OHT) vehicle to move the OHT vehicle along an overhead track of the AMHS or to operate a lifter of the OHT vehicle; and, during a deceleration phase of the transfer operation, converting kinetic energy of the OHT vehicle moving along the overhead track of the AMHS or of the lifter of the OHT vehicle to recovered electrical energy and storing the recovered electrical energy in an energy storage device.

In a nonlimiting illustrative embodiment, an OHT vehicle of an AMHS of a semiconductor fabrication facility is disclosed. The OHT vehicle includes a travel motor, a lifter configured to pick up a container of semiconductor wafers to the OHT vehicle and to place the container of semiconductor wafers from the OHT vehicle on or in an associated load port of a semiconductor processing or characterization tool, a lifter motor connected to drive the lifter, an onboard energy storage device, and a motor driver operative to perform transfer operations. Each transfer operation includes one of (i) delivering energy from the onboard energy storage device to the travel motor to move the OHT vehicle along an overhead track of the AMHS or (ii) delivering energy from the onboard energy storage device to the lifter motor to operate the lifter. The OHT vehicle further includes a relay operative to disconnect the onboard energy storage device of the OHT vehicle during an idle interval during which the OHT vehicle is not performing transfer operations.

In a nonlimiting illustrative embodiment, a method of operating an AMHS of a semiconductor fabrication facility is disclosed. The method includes: performing transfer operations to move containers of semiconductor wafers through a semiconductor fabrication facility using a plurality of OHT vehicles, the transfer operations including moving OHT vehicles along overhead tracks of the AMHS and operating lifters of the OHT vehicles to transfer the containers to and from semiconductor processing and/or characterization tools of the semiconductor fabrication facility; and during deceleration phases of the transfer operations, converting kinetic energy of the OHT vehicles moving along the overhead tracks and of the operating lifters to recovered electrical energy. The transfer operations are performed at least in part using the recovered electrical energy.

In a nonlimiting illustrative embodiment of an automated material handling system (AMHS) of a semiconductor fabrication facility, a transfer operation is performed. The transfer operation includes energizing a motor of an OHT vehicle to move the OHT vehicle along an overhead track of the AMHS, or to operate a lifter of the OHT vehicle. During a deceleration phase of the transfer operation, kinetic energy of the OHT vehicle moving along the overhead track of the AMHS, or of the lifter of the OHT vehicle, is converted to recovered electrical energy that is stored in an energy storage device. A subsequent transfer operation performed by the AMHS is powered, at least in part, using the recovered electrical energy retrieved from the energy storage device. After completion of the transfer operation, the OHT vehicle may be placed into an idle state including opening a relay to electrically disconnect the energy storage device of the OHT vehicle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating an automated material handling system (AMHS) of a semiconductor fabrication facility, the method comprising:
performing a transfer operation including energizing a motor of an overhead transport (OHT) vehicle to move the OHT vehicle along an overhead track of the AMHS or to operate a lifter of the OHT vehicle; and
during a deceleration phase of the transfer operation, converting kinetic energy of the OHT vehicle moving along the overhead track of the AMHS or of the lifter of the OHT vehicle to recovered electrical energy and storing the recovered electrical energy in an energy storage device.

2. The method of claim 1, wherein:
the transfer operation includes energizing the motor comprising a travel motor of the OHT vehicle to move the OHT vehicle along the overhead track of the AMHS; and
the converting includes converting kinetic energy of the OHT vehicle moving along the overhead track of the AMHS to recovered electrical energy.

3. The method of claim 2, wherein:
the OHT vehicle is transporting a container containing semiconductor wafers undergoing processing at the semiconductor fabrication facility; and
the transfer operation comprises moving the OHT vehicle along the overhead track of the AMHS from a position above a first semiconductor processing or characterization tool load port to a position above a second semiconductor processing or characterization tool load port.

4. The method of claim 1, wherein:
the transfer operation includes energizing the motor comprising a lifter motor of the OHT vehicle to operate the lifter of the OHT vehicle; and
the converting includes converting kinetic energy of the lifter of the OHT vehicle to recovered electrical energy.

5. The method of claim 4, wherein the transfer operation comprises one of:
lowering a container containing semiconductor wafers undergoing processing at the semiconductor fabrication facility from the OHT vehicle onto a semiconductor processing or characterization tool load port; or
raising the container containing the semiconductor wafers undergoing processing at the semiconductor fabrication facility from the semiconductor processing or characterization tool load port to the OHT vehicle.

6. The method of claim 1, further comprising:
sensing a parameter indicative of the movement of the OHT vehicle along the overhead track of the AMHS or of the lifter of the OHT vehicle; and
switching from the transfer operation to the performing of kinetic energy recovery based on the parameter indicating a deceleration of the OHT vehicle or of the lifter of the OHT vehicle.

7. The method of claim 6, wherein the sensed parameter includes at least one of a voltage of the OHT vehicle and a current of the OHT vehicle.

8. The method of claim 1, wherein the energy storage device includes:
an onboard OHT vehicle energy storage device disposed on the OHT vehicle; and
an offboard energy storage device not disposed on the OHT vehicle;
wherein the storing of the recovered electrical energy in an energy storage device includes initially storing the recovered electrical energy in the onboard OHT vehicle energy storage device and then transferring at least a portion of the recovered electrical energy from the onboard energy storage device to the offboard energy storage device via the overhead track of the AMHS.

9. The method of claim 1, further comprising:
after completion of the transfer operation, placing the OHT vehicle into an idle state including opening a relay to electrically disconnect the energy storage device of the OHT vehicle.

10. The method of claim 1, further comprising:
powering a subsequent transfer operation performed by the AMHS at least in part using the recovered electrical energy retrieved from the energy storage device.

11. An overhead transport (OHT) vehicle of an automated material handling system (AMHS) of a semiconductor fabrication facility, the OHT vehicle comprising:
a travel motor;
a lifter configured to pick up a container of semiconductor wafers to the OHT vehicle and to place the container of semiconductor wafers from the OHT vehicle on or in an associated load port of a semiconductor processing or characterization tool;
a lifter motor connected to drive the lifter;
an onboard energy storage device;
a motor driver operative to perform transfer operations, each transfer operation including one of (i) delivering energy from the onboard energy storage device to the travel motor or (ii) delivering energy from the onboard energy storage device to the lifter motor; and
a relay operative to disconnect the onboard energy storage device of the OHT vehicle.

12. The OHT vehicle of claim 11, wherein:
the motor driver includes a kinetic energy recovery system (KERS) controller operative to convert kinetic energy produced during the transfer operations into recovered electrical energy and store the recovered electrical energy in the onboard energy storage device.

13. The OHT vehicle of claim 12, wherein the KERS controller includes:
switching circuitry operative to switch between (i) delivering energy from the onboard energy storage device to the travel motor or the lifter motor, and (ii) converting kinetic energy into recovered electrical energy.

14. The OHT vehicle of claim 13, wherein the KERS controller further includes:
a boost converter; and
wherein the switching circuitry is operative to connect the boost converter to perform the energy recovery.

15. A method of operating an automated material handling system (AMHS) of a semiconductor fabrication facility, the method comprising:
performing transfer operations to move containers of semiconductor wafers through a semiconductor fabrication facility using a plurality of overhead transport (OHT) vehicles, the transfer operations including moving OHT vehicles along overhead tracks of the AMHS and operating lifters of the OHT vehicles to transfer the containers to and from semiconductor processing and/or characterization tools of the semiconductor fabrication facility; and
during deceleration phases of the transfer operations, converting kinetic energy of the OHT vehicles moving along the overhead tracks and of the operating lifters to recovered electrical energy;
wherein the transfer operations are performed at least in part using the recovered electrical energy.

16. The method of claim 15, further comprising:
at each OHT vehicle, powering the transfer operations performed by that OHT vehicle by an onboard energy storage device of the OHT vehicle; and
at each OHT vehicle, storing the recovered electrical energy that is recovered from that OHT vehicle or its lifter in the onboard OHT vehicle energy storage device.

17. The method of claim 15, further comprising:
storing at least a portion of the recovered electrical energy at an AMHS energy storage device electrically connected with the OHT vehicles by the overhead tracks.

18. The method of claim 15, wherein the converting of the kinetic energy to recovered electrical energy is performed using boost converters of the respective OHT vehicles.

19. The method of claim 15, further comprising:
opening relays of respective OHT vehicles to electrically disconnect onboard energy storage devices of the respective OHT vehicles when the respective OHT vehicles are not engaged in performing transfer operations; and
closing the relays of respective OHT vehicles to electrically connect onboard energy storage devices of the respective OHT vehicles when the respective OHT vehicles are engaged in performing transfer operations.

20. The method of claim 19, wherein the opening and closing of the relays of the OHT vehicles is controlled by an AMHS controller.
